(19) United States
(12) Patent Application Publication
(10) Pub. No.: US 2017/0248973 A1
(43) Pub. Date: Aug. 31, 2017

(54) PROBE SYSTEMS AND METHODS INCLUDING ACTIVE ENVIRONMENTAL CONTROL

(71) Applicant: Cascade Microtech, Inc., Beaverton, OR (US)

(72) Inventors: Michael Teich, Moritzburg (DE); Jörg Kiesewetter, Thiendorf OT Sacka (DE); Ulf Hackius, Dresden (DE); Frank Zill, Riesa (DE); Mirko Kreher, Grossenhain (DE)

(21) Appl. No.: 15/056,803

(22) Filed: Feb. 29, 2016

(51) Int. Cl. G05D 7/06; H01L 21/687; G01R 31/26; H01L 21/66; G01R 31/00; G05B 19/418; H01L 21/67

(52) U.S. Cl. CPC G05D 7/0635; G05B 19/41805; H01L 21/68714; H01L 21/67248; H01L 22/26; G01R 31/003; G01R 31/2642; G05B 2219/45031

(57) ABSTRACT

Probe systems and methods including active environmental control are disclosed herein. The methods include placing a substrate, which includes a device under test (DUT), on a support surface of a chuck. The support surface extends within a measurement environment that is at least partially surrounded by a measurement chamber. The methods further include determining a variable associated with a moisture content of the measurement environment and receiving a temperature associated with the measurement environment. The methods also include supplying a purge gas stream to the measurement chamber at a purge gas flow rate and selectively varying the purge gas flow rate such that a dew point temperature of the measurement environment is within a target dew point temperature range. The methods further include providing a test signal to the DUT and receiving a resultant signal from the DUT. The systems include probe systems that perform the methods.

### FIELD OF THE DISCLOSURE

The present disclosure relates generally to probe systems and methods including active environmental control, and more particularly to probe systems and methods that actively control the humidity of a measurement environment.

### BACKGROUND OF THE DISCLOSURE

In certain circumstances, it may be desirable to test the operation of a device under test (DUT) under controlled, defined, and/or regulated environmental conditions. As an example, it may be desirable to perform thermal testing to test the operation of the DUT over a range of temperatures. As another example, it may be desirable to ensure that water does not condense on the DUT during the thermal testing.

In conventional probe systems, the DUT may be placed within a measurement chamber, which at least partially surrounds the measurement environment, and a dry purge gas may be provided to the measurement chamber. A flow rate of this dry purge gas generally is not controlled and/or regulated. As such, and in order to ensure that water does not condense on the DUT, the flow rate of the dry purge gas typically is significantly higher than what theoretically would be necessary to prevent water condensation on the DUT.

While it may be effective at limiting water condensation on the DUT, this high flow rate of the dry purge gas may be detrimental to the overall performance of the probe system. As an example, the high flow rate of the dry purge gas may negatively impact a temperature uniformity of the DUT, of a substrate that supports the DUT, and/or of a chuck that supports the substrate. As another example, the high flow rate of the dry purge gas may increase an equilibration time required for the DUT, the substrate, and/or the chuck to reach a desired temperature.

As yet another example, the high flow rate of the dry purge gas may introduce mechanical noise and/or vibration into the probe system. This mechanical noise and/or vibration may negatively impact a mechanical stability of probe tips that may be utilized to test the DUT, may negatively impact the accuracy of optical pattern recognition techniques that may be utilized during the testing, and/or may introduce electrical noise into the test.

For tests that are performed over a wide range of temperatures and/or for sensitive and/or high-resolution tests, it may be desirable to decrease the above-described variations and/or noise. Thus, there exists a need for probe systems and methods that include active environmental control.

### SUMMARY OF THE DISCLOSURE

Probe systems and methods including active environmental control are disclosed herein. The methods include placing a substrate, which includes a device under test (DUT), on a support surface of a chuck. The support surface extends within a measurement environment that is at least partially surrounded by a measurement chamber. The methods further include determining a variable associated with a moisture content of the measurement environment and receiving a temperature associated with the measurement environment. The methods also include supplying a purge gas stream to the measurement chamber at a purge gas flow rate and selectively varying the purge gas flow rate such that a dew point temperature of the measurement environment is within a target dew point temperature range. The target dew point temperature range is at least a minimum dew point temperature differential below the temperature associated with the measurement environment and at most a maximum dew point temperature differential below the temperature associated with the measurement environment. The methods further include providing a test signal to the DUT and receiving a resultant signal from the DUT.

The systems include probe systems that include a measurement chamber, which at least partially surrounds a measurement environment, and a chuck, which defines a support surface that extends within the measurement environment and is configured to support a substrate that includes a DUT. The probe systems further include a probe assembly configured to provide a test signal to the DUT and/or to receive a resultant signal from the DUT. The probe systems also include a signal generation and analysis assembly configured to provide the test signal to the probe assembly and/or receive the resultant signal from the probe assembly.

The probe systems further include an environmental control assembly. The environmental control assembly includes a moisture sensor, which is configured to detect a variable associated with a moisture content of the measurement environment, a purge gas supply valve, which is configured to flow a purge gas stream into the measurement environment at a purge gas flow rate, and a controller. The controller is configured to control the operation of the purge gas supply valve based, at least in part, on the moisture content of the measurement environment.

### BRIEF DESCRIPTION OF THE DRAWINGS

FIG. 1 is a schematic representation of examples of probe systems according to the present disclosure.

FIG. 2 is a flowchart depicting methods, according to the present disclosure, of testing a device under test.

### DETAILED DESCRIPTION AND BEST MODE OF THE DISCLOSURE

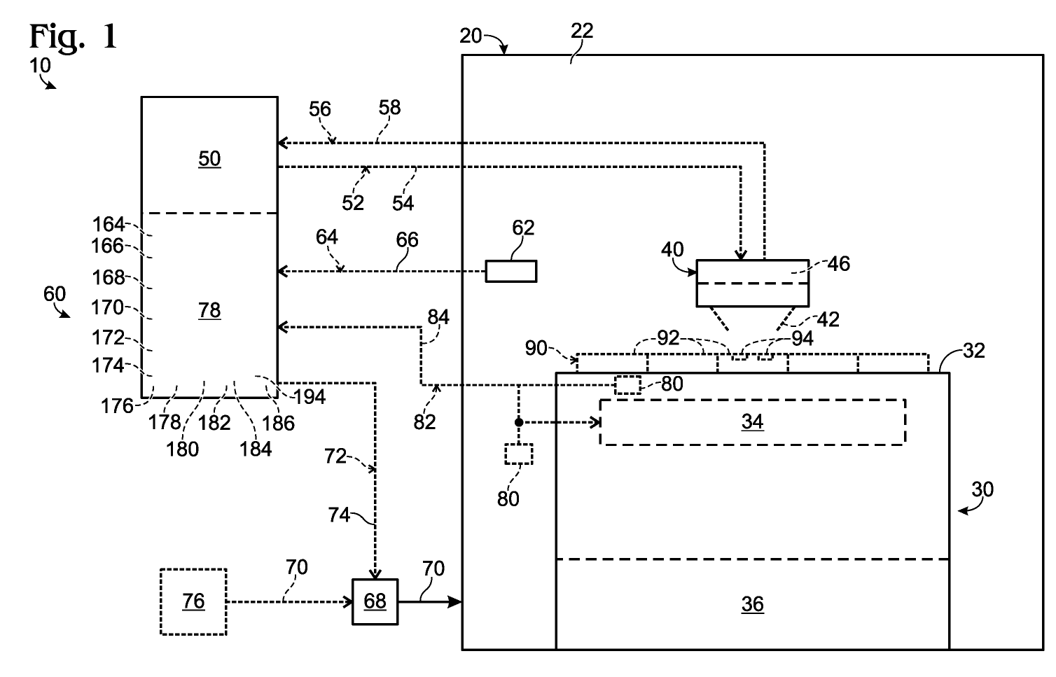

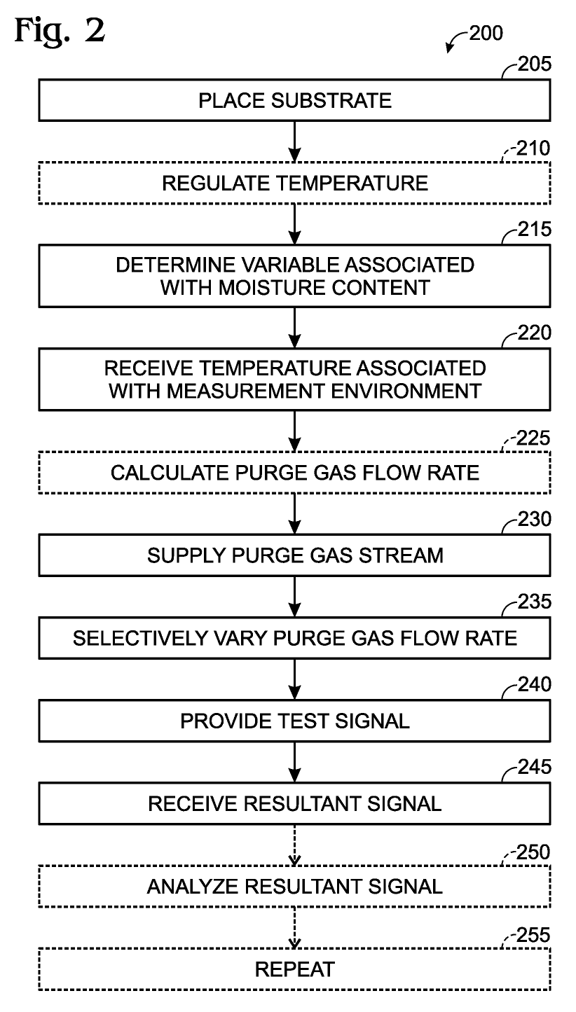

FIGS. 1-2 provide examples of probe systems 10, according to the present disclosure, and/or of methods 200, according to the present disclosure, for testing a device under test. Elements that serve a similar, or at least substantially similar, purpose may not be discussed in detail herein with reference to both of FIGS. 1-2. Elements, components, and/or features that are discussed herein with reference to one or more of FIGS. 1-2 may be included in and/or utilized with either of FIGS. 1-2 without departing from the scope of the present disclosure. In general, elements that are likely to be included in a particular embodiment are illustrated in solid lines, while elements that are optional are illustrated in dashed lines. However, elements that are shown in solid lines may not be essential and, in some embodiments, may be omitted without departing from the scope of the present disclosure.

FIG. 1 is a schematic representation of examples of probe systems 10 according to the present disclosure. Probe systems 10 include a measurement chamber 20, which at least partially surrounds, defines, and/or bounds a measurement environment 22. Probe systems 10 also include a chuck 30 that includes and/or defines a support surface 32. Support surface 32 extends within measurement environment 22 and is configured to support a substrate 90 that includes a device under test (DUT) 92. Probe systems 10 further include a probe assembly 40, which is configured to provide a test signal 54 to the DUT and/or to receive a resultant signal 58 from the DUT. A signal generation and analysis assembly 50 may be configured to provide the test signal to the probe assembly, such as via a test signal conduit 52, and/or to receive the resultant signal from the probe assembly, such as via a resultant signal conduit 56. Probe system 10 also includes an environmental control assembly 60.

During operation of probe system 10, substrate 90 may be positioned upon support surface 32 of chuck 30. Subsequently, substrate 90 and probe assembly 40 may be positioned relative to one another such that the probe assembly may test the DUT by conveying the test signal to the DUT and/or by receiving the resultant signal from the DUT. This may be accomplished, for example, by electrically contacting one or more conductive probes 42 of probe assembly 40 with one or more contact pads 94 of DUT 92. The positioning and/or contacting may be accomplished utilizing any suitable chuck translation assembly 36, which may be configured to translate chuck 30 relative to probe assembly 40, and/or any suitable probe translation assembly 46, which may be configured to translate probe assembly 40 relative to chuck 30. Before, during, and/or after testing of DUT 92, environmental control assembly 60 may control and/or regulate one or more properties of measurement environment 22, such as to prevent water condensation on substrate 90, on chuck 30, on support surface 32, and/or on another component of probe system 10 that extends within measurement chamber 20.

As used herein, the phrase, “water condensation” may refer to accumulation of water, in any form, on a given component of probe system 10. This may include the accumulation of liquid water, water droplets, water films, solid water (i.e., ice), ice crystals, and the like. In some embodiments, the presence and/or lack of water condensation may be established by visible observation (i.e., by the visibly detectable presence, or absence, of water condensation). In other embodiments, the presence and/or lack of water condensation may be established experimentally, such as by determining the presence and/or lack of water condensation in any suitable manner. In general, and as discussed, the probe systems and methods disclosed herein are configured to avoid water condensation on at least selected components of probe system 10 that extend in fluid contact with measurement environment 22. As such, the probe systems and methods are not required to include any actual observation and/or determination of the presence, or absence of water condensation on the selected components of probe system 10.

As an example, environmental control assembly 60 may include a moisture sensor 62 that may detect a moisture content of measurement environment 22 and/or of a gas that extends within measurement chamber 20 and/or that defines measurement environment 22. The environmental control assembly then may utilize a purge gas supply valve 68 to regulate flow of a purge gas stream 70 from a purge gas source 76 and/or into the measurement chamber. This purge gas stream may be a dry purge gas stream. Thus, flow of the purge gas stream into the measurement chamber may decrease a moisture content of the measurement environment, may decrease a humidity of the measurement environment, and/or may decrease a dew point of the measurement environment.

The environmental control assembly further may include a controller 78. The controller may receive a moisture signal 66 from the moisture sensor and may provide a purge gas control signal 74 to the purge gas supply valve. The purge gas supply valve may control and/or regulate a purge gas flow rate of the purge gas stream into the measurement chamber. The flow may be based upon the purge gas control signal, and the controller may generate the purge gas control signal based upon the moisture signal. Such control may be utilized to maintain a dew point temperature of the measurement environment within a target dew point temperature range. The target dew point temperature range may be less than a temperature of substrate 90, of chuck 30, of support surface 32, and/or of any other component of probe system 10 that extends within measurement chamber 20 and upon which water condensation may be undesirable and/or detrimental. As such, the environmental control assembly may prevent water condensation within at least a portion, or even all, of the measurement environment.

Controller 78 may be programmed to control the purge gas flow rate within a predetermined, and continuously variable, purge gas flow rate range. In addition, the target dew point temperature range may be only a few degrees less than the temperature of the component(s) of probe system 10 that extend within measurement chamber 20 and upon which water condensation may be undesirable and/or detrimental. As such, probe systems 10 that include environmental control assembly 60 may be configured to prevent water condensation within measurement chamber 20 while, at the same time, avoiding flow of excess, or excessive amounts of, purge gas into the measurement chamber. Such a configuration may decrease a potential for mechanical noise, vibration, electrical noise, and/or thermal gradients within the measurement environment when compared to prior art probe systems that do not include environmental control assembly 60 according to the present disclosure, that do not operate according to methods 200 that are disclosed herein, that do not regulate the purge gas flow rate based upon the moisture content of the measurement environment, and/or that do not control the purge gas flow rate within the predetermined, and continuously variable, purge gas flow rate range.

Moisture sensor 62 may include any suitable structure that may be adapted, configured, designed, and/or constructed to detect a variable associated with the moisture content of measurement environment 22, to generate the moisture signal based, at least in part, on the variable associated with the moisture content of the measurement environment, and/or to provide the moisture signal to controller 78, such as via a sensor communication conduit 64. Examples of moisture sensor 62 include any suitable chemical composition sensor, water sensor, water content sensor, water vapor sensor, moisture sensor, humidity sensor, relative humidity sensor, dew point sensor, and/or dew point temperature sensor.

Purge gas supply valve 68 may include any suitable structure that may be adapted, configured, designed, and/or constructed to flow and/or provide purge gas stream 70 into and/or to measurement chamber 20, that is configured to receive purge gas control signal 74 from controller 78, such as via a valve communication conduit 72, and/or that is configured to selectively vary the purge gas flow rate based, at least in part, on the purge gas control signal. Examples of purge gas supply valve 68 include any suitable electrically actuated valve, pneumatically actuated valve, solenoid valve, needle valve, metering valve, gate valve, ball valve, and/or butterfly valve.

Controller 78 may include any suitable structure that may be adapted, configured, designed, constructed, and/or programmed to receive the moisture signal and/or to generate the purge gas control signal based, at least in part, on the moisture signal. This may include performing any suitable portion of any suitable one of methods 200, which are discussed in more detail herein. Examples of specific components and/or structures that may be included in, may be in communication with, and/or may form a portion of controller 78 are illustrated in FIG. 1 and discussed in more detail herein. It is within the scope of the present disclosure that controller 78 may be separate and/or spaced-apart from signal generation and analysis assembly 50; however, this is not required.

Controller 78 additionally or alternatively may be programmed to generate purge gas control signal 74 based, at least in part, on a temperature that is associated with measurement environment 22. The temperature that is associated with the measurement environment may include and/or be any suitable temperature of, and/or target temperature for, any suitable structure, component, and/or material that extends within and/or defines the measurement environment. As examples, the temperature that is associated with the measurement environment may include one or more of a temperature of and/or a target temperature for measurement environment 22, the gas that extends within measurement chamber 20, DUT 92, substrate 90, chuck 30, and/or support surface 32.

As an example, controller 78 may be programmed to determine a dew point temperature of measurement environment 22 and to maintain the dew point temperature of the measurement environment below the temperature that is associated with the measurement environment. The dew point temperature may be determined based, at least in part, on moisture signal 66. The dew point temperature of the measurement environment may be maintained through regulation of the flow rate of purge gas stream 70, such as via regulation of purge gas control signal 74.

As a more specific example, controller 78 may be programmed to maintain a difference between the temperature that is associated with the measurement environment and the dew point temperature of the measurement environment within the target dew point temperature range. Examples of the target dew point temperature range are disclosed herein with reference to methods 200 of FIG. 2.

As discussed, the temperature that is associated with the measurement environment may include and/or be a target temperature, which also may be referred to herein as a desired temperature. As an example, probe system 10 may include a chuck thermal assembly 34, which may be configured to selectively control a temperature of chuck 30. This may include selectively increasing and/or decreasing the temperature of the chuck within an operating temperature range.

Under these conditions, chuck thermal assembly 34 may be configured to receive a temperature signal 84 and/or to control the temperature of chuck 30, of substrate 90, and/or of DUT 92 based, at least in part, on the temperature signal. Controller 78 may provide the temperature signal to chuck 30 and/or may receive the temperature signal from chuck 30, or from another component of probe system 10, such as via a temperature communication conduit 82. In addition, controller 78 may control the operation of purge gas supply valve 68 and/or may generate purge gas control signal 74 based, at least in part, on temperature signal 84.

As also discussed, the temperature that is associated with the measurement environment additionally or alternatively may include an actual, or measured, temperature of, or within, the measurement environment. As an example, probe system 10 may include a temperature sensor 80. Temperature sensor 80 may be configured to measure the temperature that is associated with measurement environment 22 and/or to generate temperature signal 84 based, at least in part, on the temperature that is associated with the measurement environment. Temperature communication conduit 82 then may convey temperature signal 84 to controller 78, and controller 78 may generate purge gas control signal 74 based, at least in part, on the temperature signal.

FIG. 2 is a flowchart depicting methods 200, according to the present disclosure, of testing a device under test (DUT). Methods 200 may include placing a substrate at 205 and/or regulating a temperature at 210. Methods 200 include determining a variable associated with a moisture content of a measurement environment at 215 and receiving a temperature associated with the measurement environment at 220. Methods 200 further may include calculating a purge gas flow rate at 225 and include supplying a purge gas stream at 230 and selectively varying the purge gas flow rate at 235. Methods 200 also may include providing a test signal at 240, and/or receiving a resultant signal at 245. Methods 200 further may include analyzing the resultant signal at 250 and/or repeating at least a portion of the methods at 255.

Placing the substrate at 205 may include placing the substrate, which includes the DUT, on a support surface of a chuck. This may include placing the substrate in contact with the support surface, placing the substrate in direct physical contact with the support surface, and/or placing the substrate in thermally conductive contact with the support surface. The support surface may extend within a measurement environment that is at least partially surrounded and/or defined by a measurement chamber. Such a configuration is illustrated in FIG. 1, with substrate 90, which includes DUT 92, being located on and/or in contact with support surface 32 of chuck 30.

The placing at 205 may be performed with any suitable timing and/or sequencing within methods 200. As examples, the placing at 205 may be performed prior to, concurrently with, and/or subsequent to the determining at 215, the receiving at 220, the supplying at 230, and/or the selectively varying at 235.

Regulating the temperature at 210 may include regulating the temperature of the support surface, the temperature of the chuck, and/or the temperature of the DUT. This may include regulating to a target temperature, such as to a target support surface temperature, a target chuck temperature, and/or a target DUT temperature. When methods 200 include the regulating at 210, the temperature that is associated with the measurement environment may include, or be, the target temperature. In such a configuration, methods 200 may, or may be utilized to, maintain the dew point temperature of the measurement environment below the target temperature, thereby resisting and/or preventing condensation on the chuck, on the support surface of the chuck, on the substrate, and/or on the DUT.

It is within the scope of the present disclosure that the regulating at 210 may include sequentially regulating the temperature to two or more different temperatures. As an example, the target temperature may be a first target temperature, and methods 200 may include performing the determining at 215, the receiving at 220, the calculating at 225, the supplying at 230, the selectively varying at 235, the providing at 240, and/or the receiving at 245 while the chuck, the support surface, or the DUT is at the first target temperature. Subsequently, methods 200 may include adjusting the temperature to a second, or different, target temperature and automatically repeating the determining at 215, the receiving at 220, the calculating at 225, the supplying at 230, and/or the selectively varying at 235 such that the dew point temperature of the measurement environment is at least the threshold minimum dew point differential below the second target temperature and at most the maximum dew point temperature differential below the second target temperature. Subsequently, the methods may include repeating the providing at 240 and/or the receiving at 245 to test the operation of the DUT.

The regulating at 210 may be accomplished in any suitable manner. As an example, the regulating at 210 may include regulating with and/or utilizing a chuck thermal assembly, such as chuck thermal assembly 34 of FIG. 1.

The regulating at 210 also may be performed with any suitable timing and/or sequence within methods 200. As examples, the regulating at 210 may be performed prior to, concurrently with, and/or subsequent to the placing at 205, the determining at 215, the receiving at 220, the supplying at 230, the selectively varying at 235, the providing at 240, and/or the receiving at 245.

Determining the variable associated with the moisture content of the measurement environment at 215 may include determining any suitable variable that may be based upon and/or indicative of the moisture content of the measurement environment in any suitable manner. As an example, the determining at 215 may include measuring the variable that is associated with the moisture content of the measurement environment. This may include measuring with and/or utilizing a moisture sensor, such as moisture sensor 62 of FIG. 1. As more specific examples, the determining at 215 may include determining a dew point temperature of the measurement environment, determining a relative humidity of the measurement environment, and/or determining a moisture content of a gas that extends within the measurement chamber and/or that defines the measurement environment.

Receiving the temperature associated with the measurement environment at 220 may include receiving any suitable temperature and/or any suitable signal that is, is based upon, and/or is indicative of, the temperature associated with the measurement environment. As examples, the receiving at 220 may include receiving a temperature of the DUT, a temperature of the chuck, a temperature of the support surface of the chuck, and/or a temperature of the gas that extends within the measurement chamber and/or that defines the measurement environment.

It is within the scope of the present disclosure that the receiving at 220 may include measuring the temperature associated with the measurement environment. This may include measuring with and/or utilizing a temperature sensor, such as temperature sensor 80 of FIG. 1.

Additionally or alternatively, the receiving at 220 may include receiving a target and/or desired temperature associated with the measurement environment. As an example, and when methods 200 include the regulating at 210, the receiving at 220 may include receiving the target temperature.

Calculating the purge gas flow rate at 225 may include determining and/or establishing a desired, or target, value for the purge gas flow rate in any suitable manner. As examples, the calculating at 225 may include calculating based, at least in part, on the variable associated with the measurement environment and/or on the temperature associated with the measurement environment. As an additional example, the calculating at 225 may include estimating a purge gas flow rate that is sufficient to maintain the dew point temperature of the measurement environment within a target dew point temperature range.

Supplying the purge gas stream at 230 may include supplying the purge gas stream to the measurement chamber, into the measurement chamber, and/or into fluid contact with the measurement environment. This may include supplying the purge gas stream at the purge gas flow rate, such as may be calculated during the calculating at 225. The purge gas stream may include and/or be a dry, or at least substantially dry, purge gas, or air, stream. The supplying at 230 may include supplying the dry, or at least substantially dry, purge gas, or air, stream.

Selectively varying the purge gas flow rate at 235 may include selectively varying the purge gas flow rate such that a dew point temperature of the measurement environment is within the target dew point temperature range. The target dew point temperature range may be at least a minimum dew point temperature differential below the temperature associated with the measurement environment and/or at most a maximum dew point temperature differential below the temperature associated with the measurement environment. Additionally or alternatively, the selectively varying at 235 may include selectively varying based, at least in part, on the variable associated with the moisture content of the measurement environment.

Examples of the minimum dew point temperature differential include temperature differentials of, or of at least, 1 degree Celsius, 2 degrees Celsius, 3 degrees Celsius, 4 degrees Celsius, or 5 degrees Celsius. Examples of the maximum dew point temperature differential include temperature differentials of, or of at most, 20 degrees Celsius, 15 degrees Celsius, 10 degrees Celsius, 8 degrees Celsius, 7 degrees Celsius, 6 degrees Celsius, 5 degrees Celsius, and/or 4 degrees Celsius. Stated another way, a difference between the maximum dew point temperature differential and the minimum dew point temperature differential may be less than 20 degrees Celsius, less than 15 degrees Celsius, less than 10 degrees Celsius, less than 8 degrees Celsius, less than 6 degrees Celsius, less than 4 degrees Celsius, less than 2 degrees Celsius and/or less than 1 degree Celsius.

The selectively varying at 235 may include varying within a predetermined purge gas flow rate range. This may include selectively varying within a continuously variable purge gas flow rate range that is bounded, or is bounded inclusively, between a minimum permissible purge gas flow rate and a maximum permissible purge gas flow rate. Stated another way, the purge gas flow rate may not be varied in discrete increments and instead may be varied to any suitable value that maintains the dew point temperature of the measurement environment within the target dew point temperature range and that also is within the predetermined and/or continuously variable purge gas flow rate range. This may include selectively varying to limit and/or restrict water condensation on the DUT, on the chuck, and/or on the support surface of the chuck.

As discussed, the probe systems and methods disclosed herein may be configured to avoid the flow of excess amounts of purge gas into the measurement chamber. As such, the selectively varying at 235 may include providing the purge gas stream at a minimum purge gas flow rate that is sufficient to maintain the dew point temperature of the measurement environment within the target dew point temperature range. Stated another way, the selectively varying at 235 may include minimizing the purge gas flow rate while, at the same time, maintaining the dew point temperature of the measurement environment within the target dew point temperature range. Stated yet another way, the probe systems and methods disclosed herein may include performing the selectively varying at 235 such that the target dew point temperature range is near, or only slightly below, the temperature associated with the measurement environment.

It is within the scope of the present disclosure that the selectively varying at 235 additionally or alternatively may maintain, or may be referred to herein as maintaining, a relative humidity of the measurement environment between a threshold minimum relative humidity and a threshold maximum relative humidity. Examples of the threshold minimum relatively humidity include relative humidities of 10%, 20%, 30%, 40%, 50%, 60%, and/or 70%. Examples of the threshold maximum relative humidity include relative humidities of 95%, 90%, 85%, 80%, 75%, 70%, 65%, 60%, 55%, 50%, 45%, and/or 40%.

It is within the scope of the present disclosure that the selectively varying at 235 may include utilizing feedback control to repeatedly adjust the purge gas flow rate during testing of the DUT, such as to maintain the dew point temperature of the measurement environment within the target dew point temperature range. The feedback control may include increasing, or automatically increasing, the purge gas flow rate when the dew point temperature of the measurement environment is less than the minimum dew point temperature differential below the temperature associated with the measurement environment. Additionally or alternatively, the feedback control may include decreasing, or automatically decreasing, the purge gas flow rate when the dew point temperature of the measurement environment is greater than the maximum dew point temperature differential below the temperature associated with the measurement environment.

The feedback control additionally or alternatively may include comparing the dew point temperature of the measurement environment to a target, or desired, dew point temperature of the measurement environment and selectively varying the purge gas flow rate based, at least in part, on the comparison. This may include increasing, or automatically increasing, the purge gas flow rate responsive to the dew point temperature of the measurement environment being greater than the target dew point temperature. Additionally or alternatively, this also may include decreasing, or automatically decreasing, the purge gas flow rate responsive to the dew point temperature of the measurement environment being less than the target dew point temperature.

The feedback control further may be configured to adjust, or automatically adjust, the purge gas flow rate responsive to a change in the temperature associated with the measurement environment. As an example, and when methods 200 include the regulating at 210, the regulating at 210 may include changing the temperature of the chuck, such as from the first temperature to the second temperature. Under these conditions, the feedback control may utilize the temperature of the chuck, or the target temperature, as the temperature associated with the measurement environment, and a change in the temperature of the chuck, or a change in the target temperature, automatically may cause a corresponding change in the purge gas flow rate.

Methods 200 further may include delaying an actual change in the temperature of the chuck until after the dew point temperature of the measurement environment is within the target dew point temperature range and/or may include initiating the actual change in the temperature of the chuck after the dew point temperature of the measurement environment is within the target dew point temperature range. Such a configuration may avoid water condensation on the chuck and/or on the DUT, especially when the temperature of the chuck is changed from the first temperature to a second temperature that is less than the first temperature.

Providing the test signal at 240 may include providing any suitable test signal to the DUT. This may include providing the test signal with, utilizing, and/or via a probe assembly, such as probe assembly 40 of FIG. 1. Additionally or alternatively, the providing at 240 may include generating the test signal with, or providing the test signal from, a signal generation and analysis assembly, such as signal generation and analysis assembly 50 of FIG. 1. Examples of the test signal include an electrical test signal, an electromagnetic test signal, an electric field test signal, an optical test signal, and/or a magnetic field test signal.

Receiving the resultant signal at 245 may include receiving any suitable resultant signal from the DUT. This may include receiving the resultant signal with, utilizing, and/or via the probe head assembly. Additionally or alternatively, the receiving at 245 may include receiving the resultant signal with the signal generation and analysis assembly. Examples of the resultant signal include an electrical resultant signal, an electromagnetic resultant signal, an electric field resultant signal, an optical resultant signal, and/or a magnetic field resultant signal.

It is within the scope of the present disclosure that the providing at 240 and/or the receiving at 245 may be performed with any suitable sequence and/or timing within methods 200. As examples, the providing at 240 and/or the receiving at 245 may be performed subsequent to the selectively varying at 235 and/or subsequent to the dew point temperature of the measurement environment being within the target dew point temperature range for at least a threshold soak time. As another example, methods 200 may include continuously performing at least the supplying at 230 and the selectively varying at 235 during the providing at 240 and also during the receiving at 245. As yet another example, methods 200 may include performing the providing at 240 and the receiving at 245 after performing the supplying at 230 and the selectively varying at 235 for at least a threshold equilibration time.

Analyzing the resultant signal at 250 may include analyzing the resultant signal in any suitable manner and/or for any suitable purpose. As examples, the analyzing at 250 may include analyzing to quantify operation of the DUT, to quantify one or more operational parameters of the DUT, to test operation of the DUT, and/or to test reliability of the DUT.

Repeating at least the portion of the methods at 255 may include repeating any suitable portion of methods 200. As an example, and when methods 200 include the regulating at 210, the repeating at 255 may include changing the temperature of the chuck to the second temperature and repeating at least the determining at 215, the receiving at 220, the supplying at 230, the selectively varying at 235, the providing at 240, and the receiving at 245 to test the operation of the DUT at the second temperature.

Returning to FIG. 1, probe system 10 and/or controller 78 thereof further may include a plurality of components and/or structures. Examples of these components and/or structures include a data storage device 164, a communication framework 166, a processor unit 168, a memory 170, persistent storage 172, a communication unit 174, an input/output (I/O) unit 176, a display 178, program code 180, computer readable media 182, computer readable storage media 184, computer readable signal media 186, and/or a notification system 194.

Processor unit 168 serves to run instructions that may be loaded into memory 170. Processor unit 168 may include a number of processors, a multi-processor core, or some other type of processor, depending on the particular implementation. Further, processor unit 168 may be implemented using a number of heterogeneous processor systems in which a main processor is present with secondary processors on a single chip. As another example, processor unit 168 may be a symmetric multi-processor system containing multiple processors of the same type.

Memory 170 and persistent storage 172 are examples of data storage devices 164. A data storage device 164 is any hardware device that stores, or is capable of storing, information, such as, for example, without limitation, data, program code in functional form, and other suitable information either on a temporary basis or a permanent basis.

Data storage devices 164 also may be referred to herein as computer readable storage devices and/or as computer readable storage media 184 in these examples. Memory 170, in these examples, may be, for example, a random access memory or any other suitable volatile or non-volatile storage device. Persistent storage 172 may take various forms, depending upon the particular implementation.

For example, persistent storage 172 may contain one or more components or devices. For example, persistent storage 172 may be a hard drive, a flash memory, a rewritable optical disk, a rewritable magnetic tape, or some combination of the above. The one or more components or devices used by persistent storage 172 also may be removable. For example, a removable hard drive may be used for persistent storage 172.

Communications unit 174, in these examples, provides for communications with other data processing systems or devices. In these examples, communications unit 174 may be a network interface card. Communications unit 174 may provide communications through the use of either or both physical and wireless communications links.

Input/output (I/O) unit 176 allows for input and output of data with other devices that may be connected to controller 78. For example, input/output (I/O) unit 176 may provide a connection for user input through a keyboard, a mouse, and/or some other suitable input device. Further, input/output (I/O) unit 176 may send output to a printer, to display 178, and/or to notification system 194. Display 178 provides a mechanism to display information to a user.

Instructions for the operating system, applications, and/or programs may be located in data storage devices 164, which may be in communication with processor unit 168 through communications framework 166. The instructions may be in a functional form on persistent storage 172. These instructions may be loaded into memory 170 for execution by processor unit 168. Processes of the different embodiments may be performed by processor unit 168 using computer-implemented instructions, which may be located in a memory, such as memory 170.

These instructions are referred to as program instructions, a program code 180, computer usable program code, or computer readable program code that may be read and executed by a processor in processor unit 168. The program code in the different embodiments may be located, stored, and/or embodied on different physical or computer readable storage media, such as memory 170 or persistent storage 172.

Program code 180 may be located in a functional form on computer readable media 182 that may be selectively removable and may be loaded onto or transferred to controller 78 for execution by processor unit 168. Program code 180 and computer readable media 182 may form a computer program product in these examples. In one example, computer readable media 182 may be computer readable storage media 184 or computer readable signal media 186.

Computer readable storage media 184 may include, for example, an optical or magnetic disk that is inserted or placed into a drive or other device that is part of persistent storage 172 for transfer onto a storage device, such as a hard drive, that is part of persistent storage 172. Computer readable storage media 184 also may take the form of persistent storage, such as a hard drive, a thumb drive, or a flash memory, that is connected to controller 78. In some instances, computer readable storage media 184 may not be removable from controller 78.

Computer readable storage media 184 are physical or tangible storage devices used to store program code 180 rather than media that propagate or transmit program code 180. Computer readable storage media 184 also are referred to as computer readable tangible storage devices or computer readable physical storage devices. In other words, computer readable storage media 184 are media that can be touched by a person.

Alternatively, program code 180 may be transferred to controller 78 using computer readable signal media 186. Computer readable signal media 186 may be, for example, propagated data signals containing program code 180. For example, computer readable signal media 186 may be electromagnetic signals, optical signals, and/or any other suitable type of signal. These signals may be transmitted over communications links, such as wireless communications links, optical fiber cable, coaxial cable, a wire, and/or any other suitable type of communications link. In other words, the communications link and/or the connection may be physical or wireless in the illustrative examples.

In some illustrative embodiments, program code 180 may be downloaded over a network to persistent storage 172 from another device or data processing system through computer readable signal media 186 for use within controller 78. For instance, program code stored in a computer readable storage medium in a server data processing system may be downloaded over a network from the server to controller 78. The data processing system providing program code 180 may be a server computer, a client computer, or some other device capable of storing and transmitting program code 180.

The different components illustrated for controller 78 are not meant to provide architectural limitations to the manner in which different embodiments may be implemented. The different illustrative embodiments may be implemented in a data processing system including components in addition to and/or in place of those illustrated for controller 78. Other components shown in FIG. 1 can be varied from the illustrative examples shown. The different embodiments may be implemented using any hardware device or system adapted, configured, designed, constructed, and or programmed to run program code 180. As one example, controller 78 may include organic components integrated with inorganic components and/or may be comprised entirely of organic components excluding a human being. For example, a storage device may be comprised of an organic semiconductor.

In another illustrative example, processor unit 168 may take the form of a hardware unit that has circuits that are manufactured or configured for a particular use. This type of hardware may perform operations without needing program code to be loaded into a memory from a storage device to be configured to perform the operations.

For example, when processor unit 168 takes the form of a hardware unit, processor unit 168 may be a circuit system, an application specific integrated circuit (ASIC), a programmable logic device, or some other suitable type of hardware configured to perform a number of operations. With a programmable logic device, the device is configured to perform the number of operations. The device may be reconfigured at a later time or may be permanently configured to perform the number of operations. Examples of programmable logic devices include, for example, a programmable logic array, a field programmable logic array, a field programmable gate array, and other suitable hardware devices. With this type of implementation, program code 180 may be omitted, because the processes for the different embodiments are implemented and/or embedded in a hardware unit.

In still another illustrative example, processor unit 168 may be implemented using a combination of processors found in computers and hardware units. Processor unit 168 may have a number of hardware units and a number of processors that are configured to run program code 180. With this example, some of the processes may be implemented and/or embedded in the number of hardware units, while other processes may be implemented in the number of processors.

In another example, a bus system may be used to implement communications framework 166 and may be comprised of one or more buses, such as a system bus or an input/output bus. Of course, the bus system may be implemented using any suitable type of architecture that provides for a transfer of data between different components or devices attached to the bus system.

Additionally, communications unit 174 may include a number of devices that transmit data, receive data, or both transmit and receive data. Communications unit 174 may be, for example, a modem or a network adapter, two network adapters, or some combination thereof. Further, communications unit 174 may include a memory that may be, for example, memory 170, or a cache, such as that found in an interface and memory controller hub that may be present in communications framework 166.

The flowcharts and block diagrams described herein illustrate the architecture, functionality, and operation of possible implementations of systems, methods, and computer program products according to various illustrative embodiments. In this regard, each block in the flowcharts or block diagrams may represent a module, segment, or portion of code, which comprises one or more executable instructions for implementing the specified logical function or functions. It should also be noted that, in some alternative implementations, the functions noted in a block may occur out of the order noted in the drawings. For example, the functions of two blocks shown in succession may be executed substantially concurrently, or the functions of the blocks may sometimes be executed in the reverse order, depending upon the functionality involved.

In the present disclosure, several of the illustrative, non-exclusive examples have been discussed and/or presented in the context of flow diagrams, or flow charts, in which the methods are shown and described as a series of blocks, or steps. Unless specifically set forth in the accompanying description, it is within the scope of the present disclosure that the order of the blocks may vary from the illustrated order in the flow diagram, including with two or more of the blocks (or steps) occurring in a different order and/or concurrently. It is also within the scope of the present disclosure that the blocks, or steps, may be implemented as logic, which also may be described as implementing the blocks, or steps, as logics. In some applications, the blocks, or steps, may represent expressions and/or actions to be performed by functionally equivalent circuits or other logic devices. The illustrated blocks may, but are not required to, represent executable instructions that cause a computer, processor, and/or other logic device to respond, to perform an action, to change states, to generate an output or display, and/or to make decisions.

As used herein, the term “and/or” placed between a first entity and a second entity means one of (1) the first entity, (2) the second entity, and (3) the first entity and the second entity. Multiple entities listed with “and/or” should be construed in the same manner, i.e., “one or more” of the entities so conjoined. Other entities may optionally be present other than the entities specifically identified by the “and/or” clause, whether related or unrelated to those entities specifically identified. Thus, as a non-limiting example, a reference to “A and/or B,” when used in conjunction with open-ended language such as “comprising” may refer, in one embodiment, to A only (optionally including entities other than B); in another embodiment, to B only (optionally including entities other than A); in yet another embodiment, to both A and B (optionally including other entities). These entities may refer to elements, actions, structures, steps, operations, values, and the like.

As used herein, the phrase “at least one,” in reference to a list of one or more entities should be understood to mean at least one entity selected from any one or more of the entity in the list of entities, but not necessarily including at least one of each and every entity specifically listed within the list of entities and not excluding any combinations of entities in the list of entities. This definition also allows that entities may optionally be present other than the entities specifically identified within the list of entities to which the phrase “at least one” refers, whether related or unrelated to those entities specifically identified. Thus, as a non-limiting example, “at least one of A and B” (or, equivalently, “at least one of A or B,” or, equivalently “at least one of A and/or B”) may refer, in one embodiment, to at least one, optionally including more than one, A, with no B present (and optionally including entities other than B); in another embodiment, to at least one, optionally including more than one, B, with no A present (and optionally including entities other than A); in yet another embodiment, to at least one, optionally including more than one, A, and at least one, optionally including more than one, B (and optionally including other entities). In other words, the phrases “at least one,” “one or more,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C” and “A, B, and/or C” may mean A alone, B alone, C alone, A and B together, A and C together, B and C together, A, B and C together, and optionally any of the above in combination with at least one other entity.

In the event that any patents, patent applications, or other references are incorporated by reference herein and (1) define a term in a manner that is inconsistent with and/or (2) are otherwise inconsistent with, either the non-incorporated portion of the present disclosure or any of the other incorporated references, the non-incorporated portion of the present disclosure shall control, and the term or incorporated disclosure therein shall only control with respect to the reference in which the term is defined and/or the incorporated disclosure was present originally.

As used herein the terms “adapted” and “configured” mean that the element, component, or other subject matter is designed and/or intended to perform a given function. Thus, the use of the terms “adapted” and “configured” should not be construed to mean that a given element, component, or other subject matter is simply “capable of” performing a given function but that the element, component, and/or other subject matter is specifically selected, created, implemented, utilized, programmed, and/or designed for the purpose of performing the function. It is also within the scope of the present disclosure that elements, components, and/or other recited subject matter that is recited as being adapted to perform a particular function may additionally or alternatively be described as being configured to perform that function, and vice versa.

As used herein, the phrase, “for example,” the phrase, “as an example,” and/or simply the term “example,” when used with reference to one or more components, features, details, structures, embodiments, and/or methods according to the present disclosure, are intended to convey that the described component, feature, detail, structure, embodiment, and/or method is an illustrative, non-exclusive example of components, features, details, structures, embodiments, and/or methods according to the present disclosure. Thus, the described component, feature, detail, structure, embodiment, and/or method is not intended to be limiting, required, or exclusive/exhaustive; and other components, features, details, structures, embodiments, and/or methods, including structurally and/or functionally similar and/or equivalent components, features, details, structures, embodiments, and/or methods, are also within the scope of the present disclosure.

Illustrative, non-exclusive examples of probe systems and methods according to the present disclosure are presented in the following enumerated paragraphs. It is within the scope of the present disclosure that an individual step of a method recited herein, including in the following enumerated paragraphs, may additionally or alternatively be referred to as a “step for” performing the recited action.

A1. A method of testing a device under test (DUT), the method comprising:

optionally placing a substrate, which includes the DUT, on a support surface of a chuck, wherein the support surface extends within a measurement environment that is at least partially surrounded by a measurement chamber;

determining a variable associated with a moisture content of the measurement environment;

receiving a temperature associated with the measurement environment;

supplying a purge gas stream into the measurement chamber at a purge gas flow rate;

selectively varying the purge gas flow rate such that a dew point temperature of the measurement environment is within a target dew point temperature range that is at least a minimum dew point temperature differential below the temperature associated with the measurement environment and at most a maximum dew point temperature differential below the temperature associated with the measurement environment;

optionally providing a test signal to the DUT; and

optionally receiving a resultant signal from the DUT.

A2. The method of paragraph A1, wherein the determining includes measuring the variable associated with the moisture content of the measurement environment, optionally utilizing at least one of a water sensor, a moisture sensor, a humidity sensor, a relative humidity sensor, a dew point sensor, and/or a dew point temperature sensor.

A3. The method of any of paragraphs A1-A2, wherein the determining includes determining the dew point temperature of the measurement environment.

A4. The method of any of paragraphs A1-A3, wherein the determining includes determining a relative humidity of the measurement environment.

A5. The method of any of paragraphs A1-A4, wherein the measurement environment includes a gas that extends within the measurement chamber, and further wherein the determining includes determining a moisture content of the gas.

A6. The method of any of paragraphs A1-A5, wherein the temperature associated with the measurement environment includes, and optionally is, at least one of a temperature of the DUT and a temperature of the chuck.

A7. The method of any of paragraphs A1-A6, wherein the measurement environment includes a/the gas that extends within the measurement chamber, and further wherein the temperature associated with the measurement environment includes, and optionally is, a temperature of the gas.

A8. The method of any of paragraphs A1-A7, wherein the receiving the temperature associated with the measurement environment includes measuring a temperature of the measurement environment.

A9. The method of any of paragraphs A1-A8, wherein the receiving the temperature associated with the measurement environment includes receiving a target temperature for a structure that extends within the measurement environment, optionally wherein the structure that extends within the measurement environment includes at least one of (i) at least a portion of the chuck and (ii) the support surface of the chuck.

A10. The method of any of paragraphs A1-A9, wherein the method further includes regulating a temperature of the support surface of the chuck to a/the target temperature, and further wherein the temperature associated with the measurement environment includes, and optionally is, the target temperature.

A11. The method of paragraph A10, wherein the target temperature is a first target temperature, wherein the method includes performing the providing and the receiving while the support surface of the chuck is at the target temperature, and further wherein the method includes:

adjusting the temperature of the support surface of the chuck to a second target temperature that is different from the first target temperature;

automatically repeating the determining, the receiving, the supplying, and the selectively varying such that the dew point temperature of the measurement environment is at least the minimum dew point temperature differential below the second target temperature and at most the maximum dew point temperature differential below the second target temperature; and

subsequent to the automatically repeating, repeating the providing and the receiving to test the operation of the DUT.

A12. The method of any of paragraphs A1-A11, wherein the purge gas stream includes a dry, or at least substantially dry, purge gas stream, and further wherein the supplying the purge gas stream includes supplying the dry purge gas stream.

A13. The method of any of paragraphs A1-A12, wherein the purge gas stream includes a dry, or at least substantially dry, air stream, and further wherein the supplying the purge gas stream includes supplying the dry air stream.

A14. The method of any of paragraphs A1-A13, wherein the selectively varying the purge gas flow rate includes selectively varying within a predetermined purge gas flow rate range, and optionally within a continuously variable purge gas flow rate range.

A15. The method of any of paragraphs A1-A14, wherein the selectively varying the purge gas flow rate includes selectively varying to limit, or restrict, water condensation on the DUT.

A16. The method of any of paragraphs A1-A15, wherein the selectively varying includes providing the purge gas stream at a minimum purge gas flow rate that is sufficient to maintain the dew point temperature within the target dew point temperature range.

A17. The method of any of paragraphs A1-A16, wherein the selectively varying includes minimizing the purge gas flow rate while maintaining the dew point temperature within the target dew point temperature range.

A18. The method of any of paragraphs A1-A17, wherein the selectively varying further includes maintaining a relative humidity of the measurement environment between a threshold minimum relative humidity and a threshold maximum relative humidity.

A19. The method of paragraph A18, wherein the threshold minimum relative humidity is one of 10%, 20%, 30%, 40%, 50%, 60%, or 70% relative humidity.

A20. The method of any of paragraphs A18-A19, wherein the threshold maximum relative humidity is one of 95%, 90%, 85%, 80%, 75%, 70%, 65%, 60%, 55%, 50%, 45%, or 40% relative humidity.

A21. The method of any of paragraphs A1-A20 wherein the minimum dew point temperature differential is 1 degree Celsius, 2 degrees Celsius, 3 degrees Celsius, 4 degrees Celsius, or 5 degrees Celsius.

A22. The method of any of paragraphs A1-A21, wherein the maximum dew point temperature differential is 20 degrees Celsius, 15 degrees Celsius, 10 degrees Celsius, 8 degrees Celsius, 7 degrees Celsius, 6 degrees Celsius, 5 degrees Celsius, or 4 degrees Celsius.

A23. The method of any of paragraphs A1-A22, wherein a difference between the maximum dew point temperature differential and the minimum dew point temperature differential is at least one of less than 20 degrees Celsius, less than 15 degrees Celsius, less than 10 degrees Celsius, less than 8 degrees Celsius, less than 6 degrees Celsius, less than 4 degrees Celsius, less than 2 degrees Celsius, or less than 1 degree Celsius.

A24. The method of any of paragraphs A1-A23, wherein the selectively varying is based, at least in part, on the variable associated with the moisture content of the measurement environment.

A25. The method of any of paragraphs A1-A24, wherein the selectively varying includes utilizing feedback control to repeatedly adjust the purge gas flow rate during testing of the DUT.

A26. The method of paragraph A25, wherein the utilizing feedback control includes at least one of:

(i) increasing, and optionally automatically increasing, the purge gas flow rate when the dew point temperature of the measurement environment is less than the minimum dew point temperature differential below the temperature associated with the measurement environment; and

(ii) decreasing, and optionally automatically decreasing, the purge gas flow rate when the dew point temperature of the measurement environment is greater than the maximum dew point temperature differential below the temperature associated with the measurement environment.

A27. The method of any of paragraphs A25-A26, wherein the utilizing feedback control includes comparing the dew point temperature of the measurement environment to a target dew point temperature of the measurement environment, and further wherein the selectively varying is based, at least in part, on the comparing.

A28. The method of paragraph A27, wherein the utilizing feedback control includes at least one of:

(i) increasing, and optionally automatically increasing, the purge gas flow rate responsive to the dew point temperature of the measurement environment being greater than the target dew point temperature; and

(ii) decreasing, and optionally automatically decreasing, the purge gas flow rate responsive to the dew point temperature of the measurement environment being less than the target dew point temperature.

A29. The method of any of paragraphs A25-A28, wherein the utilizing feedback control includes automatically adjusting the purge gas flow rate responsive to a change in the temperature associated with the measurement environment.

A30. The method of any of paragraphs A1-A29, wherein the method further includes calculating the purge gas flow rate based, at least in part, on the variable associated with the moisture content of the measurement environment and the temperature associated with the measurement environment.

A31. The method of any of paragraphs A1-A30, wherein the providing the test signal includes providing at least one of an electrical test signal, an electromagnetic test signal, an electric field test signal, an optical test signal, and a magnetic field test signal.

A32. The method of any of paragraphs A1-A31, wherein the receiving the resultant signal includes receiving at least one of an electrical resultant signal, an electromagnetic resultant signal, an electric field resultant signal, an optical resultant signal, and a magnetic field resultant signal.

A33. The method of any of paragraphs A1-A32, wherein the method further includes analyzing the resultant signal to quantify operation of the DUT.

A34. The method of any of paragraphs A1-A33, wherein the method includes performing the providing and the receiving subsequent to the dew point temperature being within the target dew point temperature range for at least a threshold soak time.

A35. The method of any of paragraphs A1-A34, wherein the method includes continuously performing at least the supplying and the selectively varying during the providing and the receiving.

A36. The method of any of paragraphs A1-A35, wherein the method includes performing the providing and the receiving after performing the supplying and the selectively varying for at least a threshold equilibration time.

A37. The method of any of paragraphs A1-A36, wherein the placing includes placing the substrate at least one of in contact with the support surface of the chuck, in direct physical contact with the support surface of the chuck, and in thermally conductive contact with the support surface of the chuck.

A38. The method of any of paragraphs A1-A37, wherein the placing includes at least one of placing prior to the determining, placing prior to the receiving, placing prior to the supplying, and placing prior to the selectively varying.

A39. The method of any of paragraphs A1-A38, wherein the placing includes at least one of placing concurrently with the determining, placing concurrently with the receiving, placing concurrently with the supplying, and placing concurrently with the selectively varying.

A40. The method of any of paragraphs A1-A39, wherein the placing includes at least one of placing subsequent to the determining, placing subsequent to the receiving, placing subsequent to the supplying, and placing subsequent to the selectively varying.

B1. A probe system, comprising:

a measurement chamber that at least partially surrounds a measurement environment;

a chuck defining a support surface that extends within the measurement environment and is configured to support a substrate that includes a device under test (DUT);

a probe assembly configured to at least one of provide a test signal to the DUT and receive a resultant signal from the DUT;

a signal generation and analysis assembly configured to at least one of provide the test signal to the probe assembly and receive the resultant signal from the probe assembly; and

an environmental control assembly, comprising:
(i) a moisture sensor configured to detect a variable associated with a moisture content of the measurement environment and to generate a moisture signal that is based, at least in part, on the variable associated with the moisture content of the measurement environment;
(ii) a purge gas supply valve configured to flow a purge gas stream into the measurement chamber at a purge gas flow rate, wherein the purge gas supply valve further is configured to receive a purge gas control signal and to selectively vary the purge gas flow rate based, at least in part, on the purge gas control signal and within a predetermined, and continuously variable, purge gas flow rate range; and
(iii) a controller programmed to receive the moisture signal from the moisture sensor and to generate the purge gas control signal based, at least in part, on the moisture signal.

B2. The system of paragraph B1, wherein the controller further is programmed to generate the purge gas control signal based, at least in part, on a temperature associated with the measurement environment.

B3. The system of paragraph B2, wherein the temperature associated with the measurement environment includes at least one of:
(i) a temperature of the DUT;
(ii) a temperature of the chuck;
(iii) a temperature of the support surface of the chuck; and
(iv) a temperature of a gas that extends within the measurement chamber.

B4. The system of any of paragraphs B2-B3, wherein the temperature associated with the measurement environment includes a target temperature for a structure that extends within the measurement environment, optionally wherein the structure that extends within the measurement environment includes at least one of at least a portion of the chuck and the support surface of the chuck.

B5. The system of any of paragraphs B2-B4, wherein the probe system further includes a chuck thermal assembly configured to selectively control a temperature of the chuck to a/the target temperature, and further wherein the temperature associated with the measurement environment includes the target temperature.

B6. The system of any of paragraphs B2-B5, wherein the controller is programmed to determine a dew point temperature of the measurement environment based, at least in part, on the moisture signal, and to regulate the purge gas flow rate, via the purge gas control signal, to maintain the dew point temperature of the measurement environment below the temperature associated with the measurement environment.

B7. The system of paragraph B6, wherein the controller is programmed to maintain a difference between the temperature associated with the measurement chamber and the dew point temperature of the measurement environment within a target dew point temperature range, optionally wherein the target dew point temperature range is at least one of:

(i) at least 1 degree Celsius, at least 2 degrees Celsius, at least 3 degrees Celsius, at least 4 degrees Celsius, or at least 5 degrees Celsius less than the temperature associated with the measurement environment; and

(ii) at most 20 degrees Celsius, at most 15 degrees Celsius, at most 10 degrees Celsius, at most 8 degrees Celsius, at most 7 degrees Celsius, at most 6 degrees Celsius, at most 5 degrees Celsius, or at most 4 degrees Celsius less than the temperature associated with the measurement environment.

B8. The system of any of paragraphs B1-B7, wherein the controller is programmed to control the operation of the purge gas supply valve, via the purge gas control signal, by performing the method of any of paragraphs A1-A40.

B9. The system of any of paragraphs B1-B8, wherein the probe system further includes a sensor communication conduit configured to convey the moisture signal from the moisture sensor to the controller.

B10. The system of any of paragraphs B1-B9, wherein the probe system further includes a valve communication conduit configured to convey the purge gas control signal from the controller to the purge gas supply valve.

C1. Computer readable storage media including computer-executable instructions that, when executed, direct a probe system to perform the method of any of paragraphs A1-A40.

D1. The use of any of the probe systems of any of paragraphs B1-B10 with any of the methods of any of paragraphs A1-A40.

D2. The use of any of the methods of any of paragraphs A1-A40 with any of the probe systems of any of paragraphs B1-B10.

D3. The use of any of the methods of any of paragraphs A1-A40 or any of the probe systems of any of paragraphs B1-B10 to restrict water condensation on a device under test.

D4. The use of a probe system that includes an environmental control assembly to restrict water condensation on a device under test.

### INDUSTRIAL APPLICABILITY

The probe systems and methods disclosed herein are applicable to the semiconductor manufacturing and test industries.

It is believed that the disclosure set forth above encompasses multiple distinct inventions with independent utility. While each of these inventions has been disclosed in its preferred form, the specific embodiments thereof as disclosed and illustrated herein are not to be considered in a limiting sense as numerous variations are possible. The subject matter of the inventions includes all novel and non-obvious combinations and subcombinations of the various elements, features, functions and/or properties disclosed herein. Similarly, where the claims recite “a” or “a first” element or the equivalent thereof, such claims should be understood to include incorporation of one or more such elements, neither requiring nor excluding two or more such elements.

It is believed that the following claims particularly point out certain combinations and subcombinations that are directed to one of the disclosed inventions and are novel and non-obvious. Inventions embodied in other combinations and subcombinations of features, functions, elements and/or properties may be claimed through amendment of the present claims or presentation of new claims in this or a related application. Such amended or new claims, whether they are directed to a different invention or directed to the same invention, whether different, broader, narrower, or equal in scope to the original claims, are also regarded as included within the subject matter of the inventions of the present disclosure.

1. A method of testing a device under test (DUT), the method comprising:
placing a substrate, which includes the DUT, on a support surface of a chuck, wherein the support surface extends within a measurement environment that is at least partially surrounded by a measurement chamber;
determining a variable associated with a moisture content of the measurement environment;
receiving a temperature associated with the measurement environment;
supplying a purge gas stream into the measurement chamber at a purge gas flow rate;
selectively varying the purge gas flow rate such that a dew point temperature of the measurement environment is within a target dew point temperature range that is at least a minimum dew point temperature differential below the temperature associated with the measurement environment and at most a maximum dew point temperature differential below the temperature associated with the measurement environment;
providing a test signal to the DUT; and
receiving a resultant signal from the DUT.

2. The method of claim 1, wherein the determining includes measuring the variable associated with the moisture content of the measurement environment.

3. The method of claim 1, wherein the determining includes determining the dew point temperature of the measurement environment.

4. The method of claim 1, wherein the temperature associated with the measurement environment includes at least one of a temperature of the DUT and a temperature of the chuck.

5. The method of claim 1, wherein the receiving the temperature associated with the measurement environment includes receiving a target temperature for a structure that extends within the measurement environment.

6. The method of claim 5, wherein the structure that extends within the measurement environment includes at least one of (i) at least a portion of the chuck and (ii) the support surface of the chuck.

7. The method of claim 1, wherein the method further includes regulating a temperature of the support surface of the chuck to a target temperature, and further wherein the temperature associated with the measurement environment includes, and optionally is, the target temperature.

8. The method of claim 7, wherein the target temperature is a first target temperature, wherein the method includes performing the providing and the receiving while the support surface of the chuck is at the first target temperature, and further wherein the method includes:
adjusting the temperature of the support surface of the chuck to a second target temperature that is different from the first target temperature;
automatically repeating the determining, the receiving, the supplying, and the selectively varying such that the dew point temperature of the measurement environment is at least the minimum dew point temperature differential below the second target temperature and at most the maximum dew point temperature differential below the second target temperature; and
subsequent to the automatically repeating, repeating the providing and the receiving to test the operation of the DUT.

9. The method of claim 1, wherein the purge gas stream includes an at least substantially dry purge gas stream, and further wherein the supplying the purge gas stream includes supplying the at least substantially dry purge gas stream.

10. The method of claim 1, wherein the selectively varying the purge gas flow rate includes selectively varying within a predetermined, and continuously variable, purge gas flow rate range.

11. The method of claim 1, wherein the selectively varying includes minimizing the purge gas flow rate while maintaining the dew point temperature within the target dew point temperature range.

12. The method of claim 1, wherein the minimum dew point temperature differential is 2 degrees Celsius and the maximum dew point temperature differential is 6 degrees Celsius.

13. The method of claim 1, wherein a difference between the maximum dew point temperature differential and the minimum dew point temperature differential is less than 4 degrees Celsius.

14. The method of claim 1, wherein the selectively varying is based, at least in part, on the variable associated with the moisture content of the measurement environment.

15. The method of claim 1, wherein the selectively varying includes utilizing feedback control to repeatedly adjust the purge gas flow rate during testing of the DUT by at least one of:
(i) increasing the purge gas flow rate when the dew point temperature of the measurement environment is less than the minimum dew point temperature differential below the temperature associated with the measurement environment; and
(ii) decreasing the purge gas flow rate when the dew point temperature of the measurement environment is greater than the maximum dew point temperature differential below the temperature associated with the measurement environment.

16. The method of claim 1, wherein the selectively varying includes utilizing feedback control to repeatedly adjust the purge gas flow rate during testing of the DUT, wherein the utilizing feedback control includes comparing the dew point temperature of the measurement environment to a target dew point temperature of the measurement environment and at least one of:
(i) increasing the purge gas flow rate responsive to the dew point temperature of the measurement environment being greater than the target dew point temperature; and
(ii) decreasing the purge gas flow rate responsive to the dew point temperature of the measurement environment being less than the target dew point temperature.

17. The method of claim 16, wherein the utilizing feedback control includes automatically adjusting the purge gas flow rate responsive to a change in the temperature associated with the measurement environment.

18. The method of claim 1, wherein the method includes continuously performing at least the supplying and the selectively varying during the providing and the receiving.

19. Computer readable storage media including computer-executable instructions that, when executed, direct a probe system to perform the method of claim 1.

20. A probe system, comprising:
a measurement chamber that at least partially surrounds a measurement environment;
a chuck defining a support surface that extends within the measurement environment and is configured to support a substrate that includes a device under test (DUT);
a probe assembly configured to at least one of provide a test signal to the DUT and receive a resultant signal from the DUT;
a signal generation and analysis assembly configured to at least one of provide the test signal to the probe assembly and receive the resultant signal from the probe assembly; and
an environmental control assembly, comprising:
(i) a moisture sensor configured to detect a variable associated with a moisture content of the measurement environment and to generate a moisture signal that is based, at least in part, on the variable associated with the moisture content of the measurement environment;
(ii) a purge gas supply valve configured to flow a purge gas stream into the measurement chamber at a purge gas flow rate, wherein the purge gas supply valve further is configured to receive a purge gas control signal and to selectively vary the purge gas flow rate based, at least in part, on the purge gas control signal and within a predetermined, and continuously variable, purge gas flow rate range; and
(iii) a controller programmed to receive the moisture signal from the moisture sensor and to generate the purge gas control signal based, at least in part, on the moisture signal.
